(19) United States
(12) Patent Application Publication
(10) Pub. No.: US 2026/0254214 A1
(43) Pub. Date: Aug. 27, 2026

(54) FLAT WIRING MATERIAL CASE

(71) Applicant: Yazaki Corporation, Tokyo (JP)

(72) Inventors: Katsunori SATO, Shizuoka (JP); Tatsuya Oga, Shizuoka (JP); Mariko Nakagawa, Shizuoka (JP); Masato Tanaka, Shizuoka (JP)

(73) Assignee: Yazaki Corporation, Tokyo (JP)

(21) Appl. No.: 19/652,053

(22) Filed: Apr. 20, 2026

Related U.S. Application Data
(63) Continuation of application No. PCT/JP2024/044185, filed on Dec. 13, 2024.

(30) Foreign Application Priority Data
Jan. 15, 2024 (JP) 2024-003698
Mar. 14, 2024 (JP) 2024-039838

(51) Int. Cl. H02G 3/06; H02G 3/04

(52) U.S. Cl. CPC H02G 3/0608; H02G 3/0437; H02G 3/0456

(57) ABSTRACT

A flat wiring material case includes a first case including an accommodation space, a holding portion, and a first engagement portion, and a second case including an accommodation space, a holding portion, and a second engagement portion, wherein the first case and the second case have an extension direction in which the flat wiring material extends, the first case and the second case are configured to be disposed at a first relative position and a second relative position, the first case and the second case are disposed side by side in a direction orthogonal to the extension direction at the first relative position, the first case and the second case are linearly disposed along the extension direction at the second relative position, and the first case and the second case are fixed at the second relative position.

### CROSS-REFERENCE TO RELATED APPLICATION(S)

This application is a continuation application of International Application No. PCT/JP2024/044185 filed on December 13, 2024 which claims the benefit of priority from Japanese Patent Application No. 2024-003698 filed on January 15, 2024 and Japanese Patent Application No. 2024-039838 filed on March 14, 2024 and designating the U.S., the entire contents of which are incorporated herein by reference.

### BACKGROUND OF THE INVENTION

### 1. Field of the Invention

The present invention relates to a flat wiring material case.

### 2. Description of the Related Art

In the related art, there is a case that accommodates a wiring material. For example, the battery bus bar module of JP 2022 – 108 301 A includes a case that accommodates a plurality of bus bars and a battery sensing unit.

It is desired to improve the conveyability of the case accommodating the flat wiring material. For example, in a case where the case is increased in size in accordance with an increase in length of the flat wiring material to be accommodated, the conveyability of the case is likely to deteriorate.

### SUMMARY OF THE INVENTION

An object of the present invention is to provide a flat wiring material case capable of improving conveyability.

In order to achieve the above mentioned object, a flat wiring material case according to one aspect of the present invention includes a first case including an accommodation space in which a first portion of a flat wiring material is accommodated, a holding portion that holds the first portion, and a first engagement portion; and a second case including an accommodation space in which a second portion of the flat wiring material is accommodated, a holding portion that holds the second portion, and a second engagement portion, wherein the first case and the second case have an extension direction in which the flat wiring material extends, wherein the first case and the second case are configured to be either disposed at a first relative position or disposed at a second relative position, wherein the first case and the second case are disposed side by side in a direction orthogonal to the extension direction and in a width direction of the flat wiring material accommodated in the first case and the second case at the first relative position, wherein the first case and the second case are linearly disposed along the extension direction at the second relative position, and wherein the first engagement portion and the second engagement portion are engaged with each other at the second relative position to fix the first case and the second case.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a plan view of a flat wiring material case according to the embodiment;

FIG. 2 is a plan view of the flat wiring material case according to the embodiment;

FIG. 3 is a cross-sectional view of the flat wiring material case according to the embodiment;

FIG. 4 is a perspective view of the flat wiring material case according to the embodiment;

FIG. 5 is a plan view of a flat wiring material according to the embodiment;

FIG. 6 is a plan view of the flat wiring material case assembled to the flat wiring material;

FIG. 7 is a cross-sectional view of the flat wiring material case assembled to the flat wiring material;

FIG. 8 is a plan view of the flat wiring material case assembled to the flat wiring material;

FIG. 9 is a view illustrating an intermediate portion accommodated in the flat wiring material case;

FIG. 10 is a perspective view of the flat wiring material case according to the embodiment;

FIG. 11 is a perspective view of the flat wiring material case according to the embodiment;

FIG. 12 is a perspective view of the flat wiring material case according to the embodiment;

FIG. 13 is a view illustrating an example of the flat wiring material;

FIG. 14 is a view illustrating an example of the flat wiring material;

FIG. 15 is a plan view of the flat wiring material case according to the embodiment;

FIG. 16 is a view illustrating an example of the flat wiring material;

FIG. 17 is a view illustrating an example of the flat wiring material;

FIG. 18 is a developed view of a flat wiring material case according to a modification of the embodiment;

FIG. 19 is a perspective view of the flat wiring material case according to the modification of the embodiment;

FIG. 20 is a plan view of the flat wiring material according to the modification of the embodiment;

FIG. 21 is a plan view illustrating the flat wiring material accommodated in a case according to the modification of the embodiment;

FIG. 22 is a plan view of the flat wiring material case in a state where the cover is closed;

FIG. 23 is a plan view illustrating a first case and a second case positioned at an intermediate relative position;

FIG. 24 is a cross-sectional perspective view illustrating the bent flat wiring material;

FIG. 25 is a perspective view for describing relative rotation of the second case with respect to the first case;

FIG. 26 is a perspective view of the first case and the second case positioned at a second relative position;

FIG. 27 is a plan view of the flat wiring material case having a coupling structure;

FIG. 28 is a perspective view illustrating an example of the coupling structure;

FIG. 29 is a view illustrating the first case and the second case positioned at an intermediate relative position in a modification of the embodiment;

FIG. 30 is a perspective view illustrating an example of a rotation structure; and

FIG. 31 is a view illustrating the first case and the second case positioned at a second relative position in a modification of the embodiment.

### DETAILED DESCRIPTION OF THE PREFERRED EMBODIMENTS

Hereinafter, a flat wiring material case according to an embodiment of the present invention will be described in detail with reference to the drawings. Note that the present invention is not limited by the embodiment. In addition, constituent elements in the following embodiments include those that can be easily assumed by those skilled in the art or those that are substantially the same.

### Embodiments

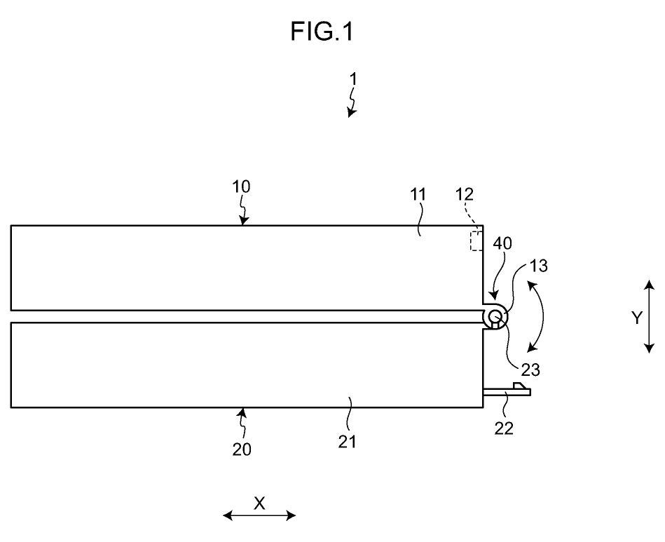

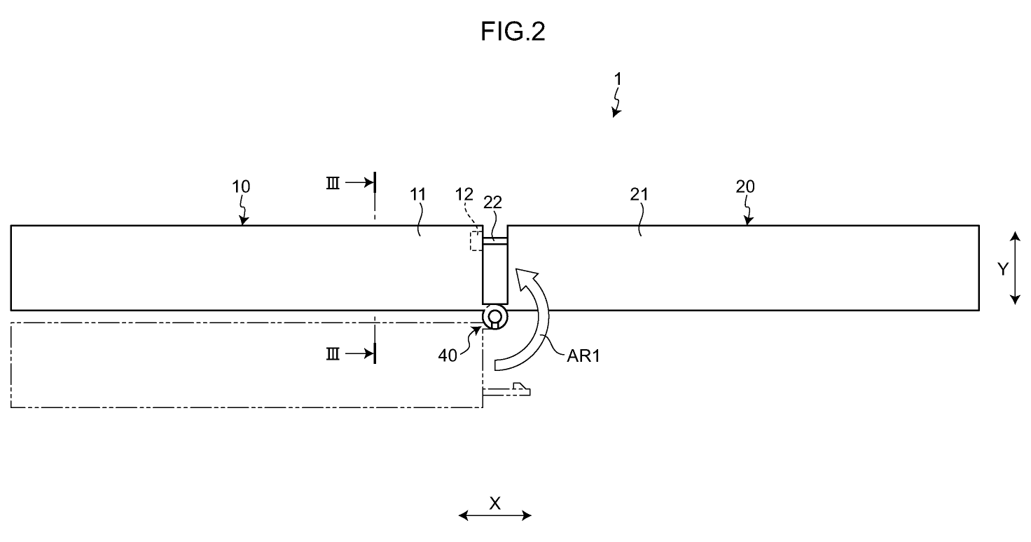

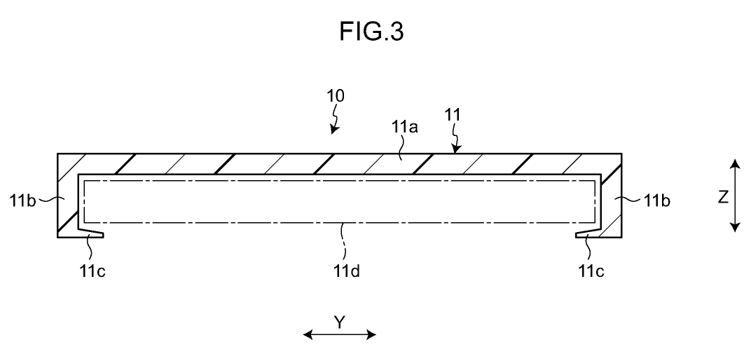

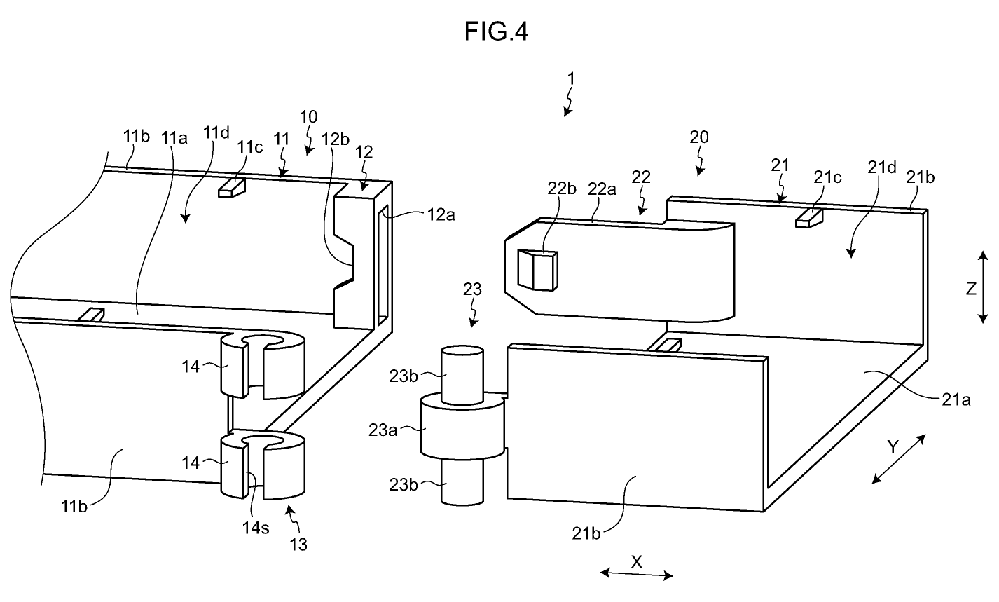

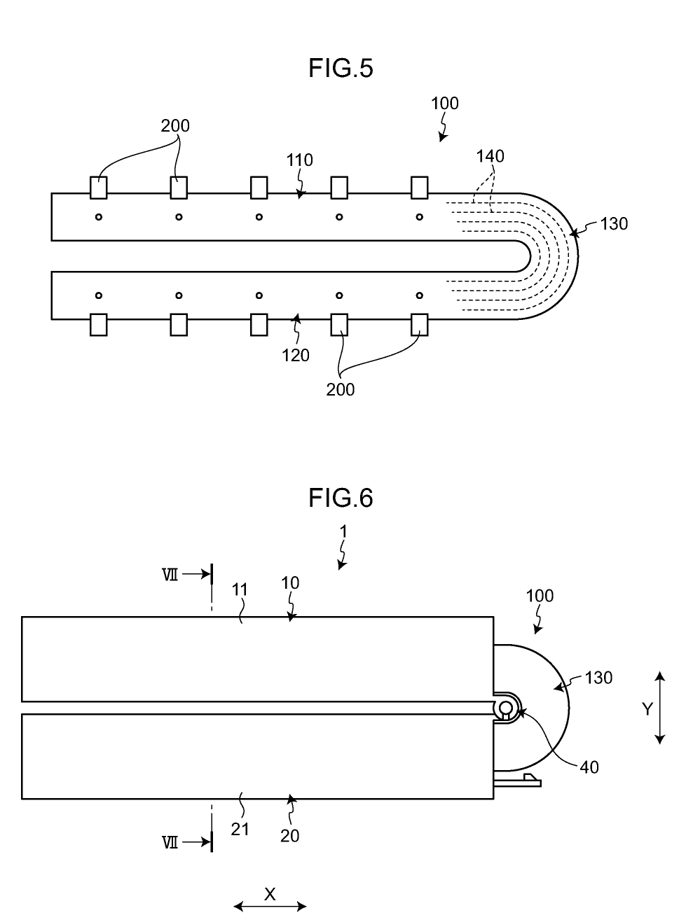

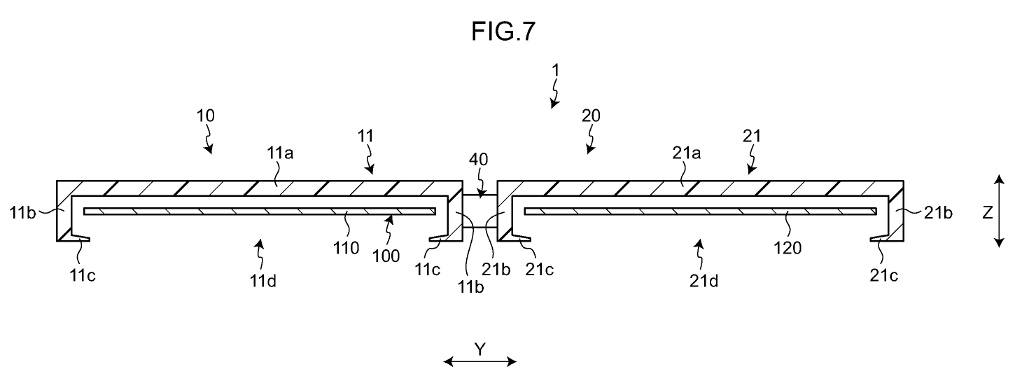

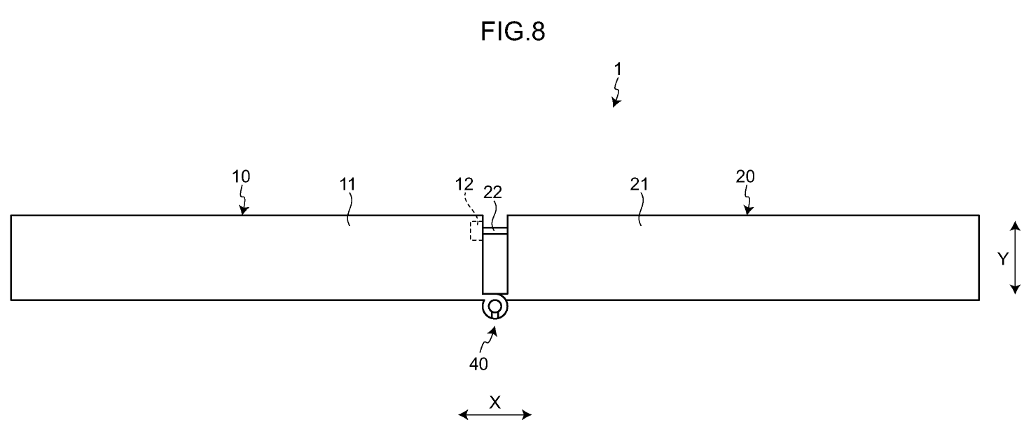

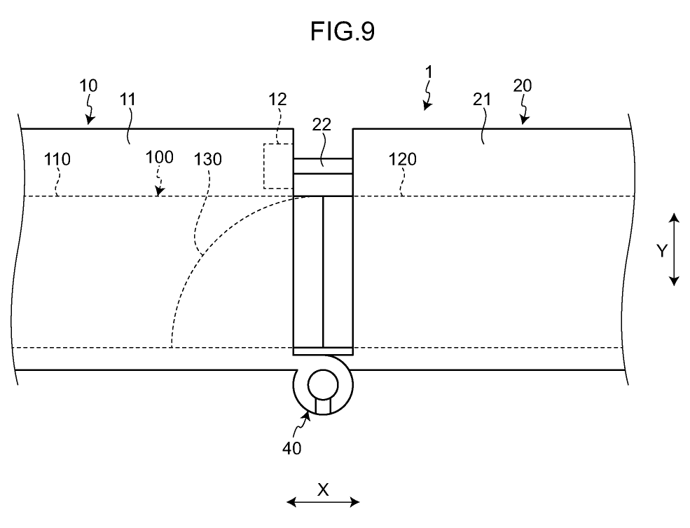

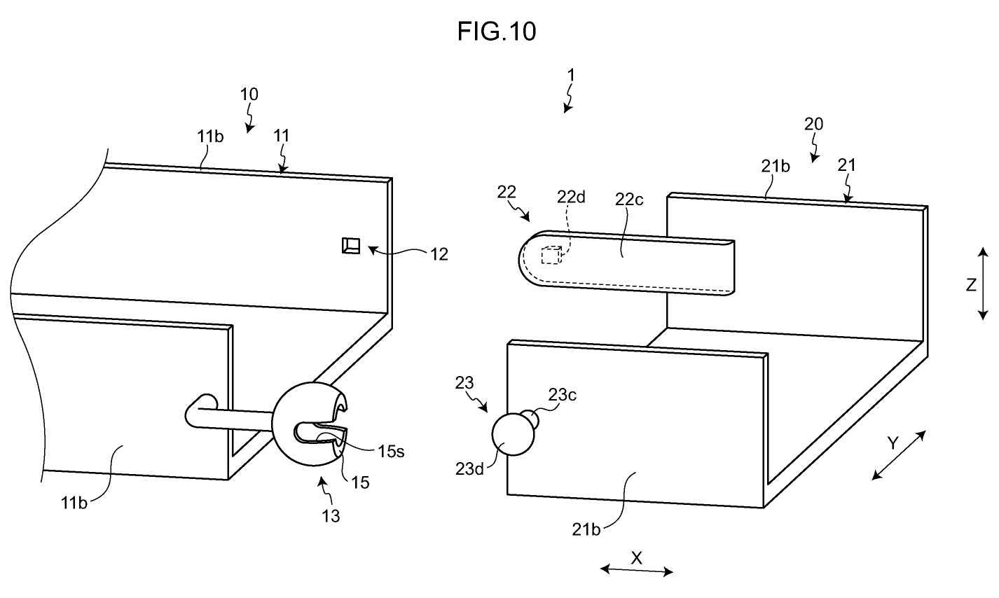

An embodiment will be described with reference to FIGS. 1 to 17. The present embodiment relates to a flat wiring material case. FIGS. 1 and 2 are plan views of a flat wiring material case according to the embodiment, FIG. 3 is a cross-sectional view of the flat wiring material case according to the embodiment, FIG. 4 is a perspective view of the flat wiring material case according to the embodiment, FIG. 5 is a plan view of the flat wiring material according to the embodiment, FIG. 6 is a plan view of the flat wiring material case assembled to the flat wiring material, FIG. 7 is a cross-sectional view of the flat wiring material case assembled to the flat wiring material, FIG. 8 is a plan view of the flat wiring material case assembled to the flat wiring material, FIG. 9 is a view illustrating an intermediate portion accommodated in the flat wiring material case, and FIGS. 10 to 12 are perspective views of the flat wiring material case according to the embodiment.

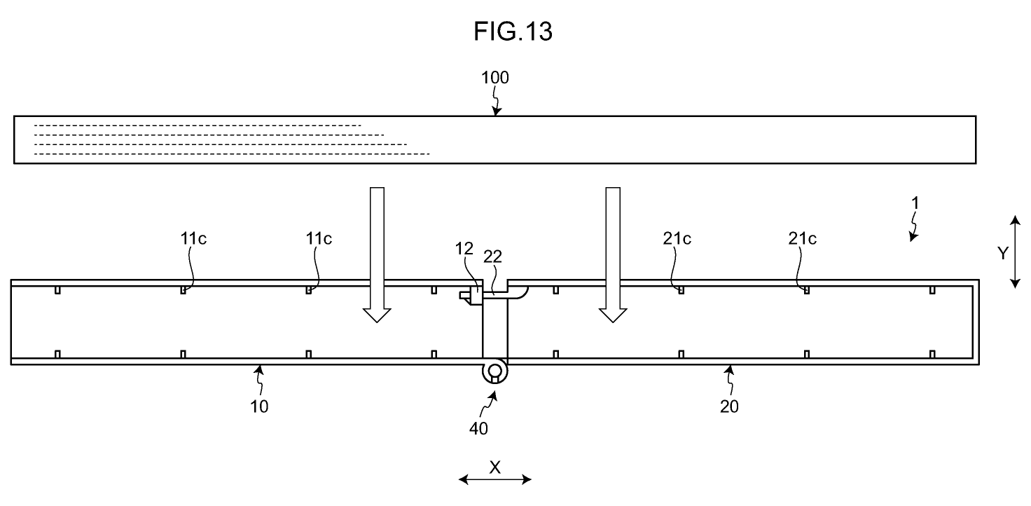

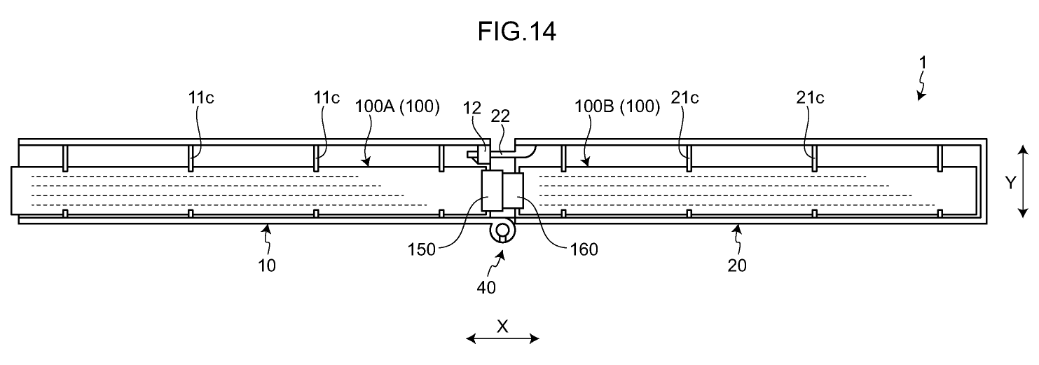

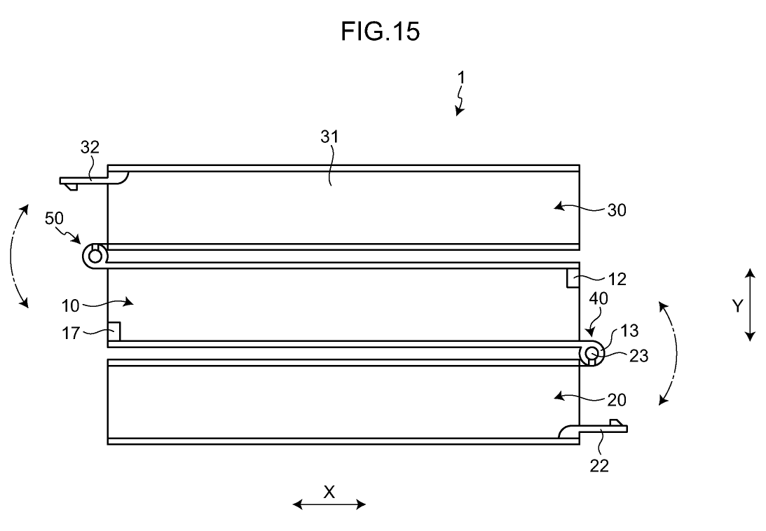

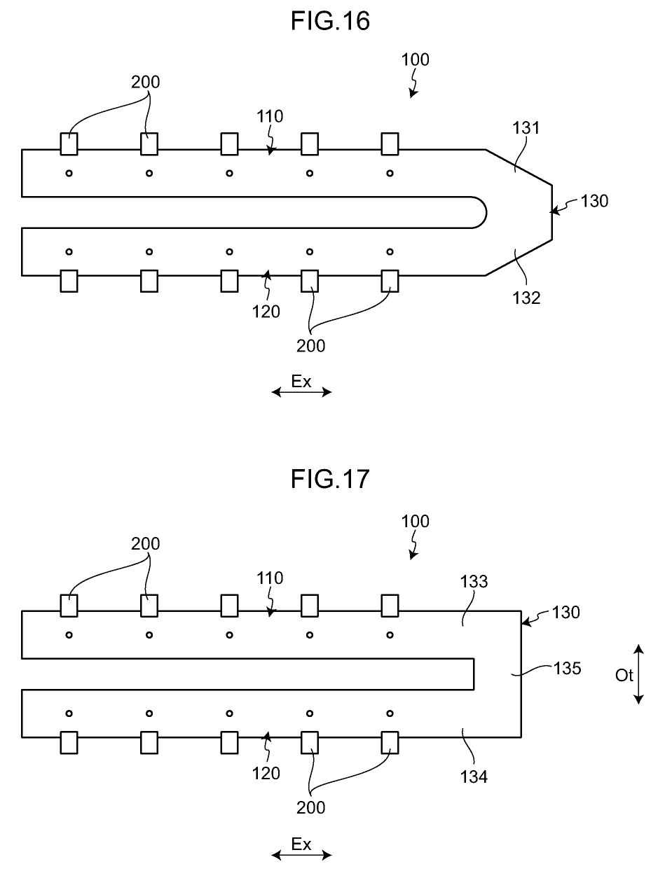

FIGS. 13 and 14 are views illustrating an example of the flat wiring material, FIG. 15 is a plan view of the flat wiring material case according to the embodiment, and FIGS. 16 and 17 are views illustrating an example of the flat wiring material. FIG. 3 illustrates a cross section taken along line III-III in FIG. 2. FIG. 7 illustrates a cross section taken along line VII-VII in FIG. 6.

As illustrated in FIGS. 1 and 2, a flat wiring material case 1 of the present embodiment includes a first case 10 and a second case 20. The first case 10 and the second case 20 are formed of, for example, insulating synthetic resin. The first case 10 and the second case 20 illustrated in FIGS. 1 and 2 are coupled so as to be relatively rotatable. The flat wiring material case 1 is used, for example, when a flat wiring material 100 having a substantially U-shape as illustrated in FIG. 5 is deformed into a linear shape and held.

As illustrated in FIG. 1, the first case 10 includes a main body 11, a first engagement portion 12, and a first coupling portion 13. The main body 11, the first engagement portion 12, and the first coupling portion 13 are integrally molded, for example. The second case 20 includes a main body 21, a second engagement portion 22, and a second coupling portion 23. The main body 21, the second engagement portion 22, and the second coupling portion 23 are integrally molded, for example. Each of the first case 10 and the second case 20 is configured to be capable of accommodating the flat wiring material 100.

As illustrated in FIGS. 1 and 2, the first case 10 and the second case 20 have an extension direction X and a width direction Y. The extension direction X is a direction in which the flat wiring material 100 accommodated in the cases 10 and 20 extends. In other words, the extension direction X is an axial direction and a longitudinal direction of the flat wiring material 100 accommodated in the cases 10 and 20. The width direction Y is a width direction of the flat wiring material 100 accommodated in the cases 10 and 20. The width direction Y is orthogonal to the extension direction X.

As illustrated in FIG. 3, the main body 11 of the first case 10 has an accommodation space 11d in which the flat wiring material can be accommodated. More specifically, the main body 11 of the first case 10 includes a support wall 11a, a pair of side walls 11b, and a plurality of holding portions 11c. The support wall 11a, the side wall 11b, and the holding portion 11c are integrated, for example. The illustrated support wall 11a and the illustrated side wall 11b have a flat plate shape. The side wall 11b is erected from an edge of the support wall 11a and is orthogonal to the support wall 11a. The pair of side walls 11b faces each other in the width direction Y. The support wall 11a and the pair of side walls 11b form the accommodation space 11d in which the flat wiring material 100 is accommodated.

The holding portion 11c holds the flat wiring material 100 accommodated in the accommodation space 11d. Each side wall 11b has a plurality of holding portions 11c. The plurality of holding portions 11c is disposed at intervals along the extension direction X. The holding portion 11c protrudes from the side wall 11b in the width direction Y. The holding portion 11c provided at one side wall 11b protrudes toward the other side wall 11b. The holding portion 11c has a claw shape, and can hold the flat wiring material 100 so that the flat wiring material 100 does not fall off from the accommodation space 11d.

The main body 21 of the second case 20 has substantially the same shape as the main body 11 of the first case 10. As illustrated in FIG. 4, the main body 21 includes a support wall 21a, a pair of side walls 21b, and a plurality of holding portions 21c. The side wall 21b is erected from an edge of the support wall 21a and is orthogonal to the support wall 21a. The pair of side walls 21b faces each other in the width direction Y. The support wall 21a and the pair of side walls 21b form an accommodation space 21d in which the flat wiring material 100 is accommodated.

The holding portion 21c holds the flat wiring material 100 accommodated in the accommodation space 21d. Each side wall 21b has a plurality of holding portions 21c. The plurality of holding portions 21c is disposed at intervals along the extension direction X. The holding portion 21c protrudes from the side wall 21b in the width direction Y. The holding portion 21c provided at one side wall 21b protrudes toward the other side wall 21b. The holding portion 21c has a claw shape, and can hold the flat wiring material 100 so that the flat wiring material 100 does not fall off from the accommodation space 21d.

The first engagement portion 12 and the second engagement portion 22 illustrated in FIG. 4 are engaged with each other along the extension direction X. The second engagement portion 22 includes a piece portion 22a and a protrusion 22b. The piece portion 22a protrudes from the end face of the side wall 21b in the extension direction X. The protrusion 22b protrudes in the width direction Y from the tip of the piece portion 22a.

The first engagement portion 12 has a frame shape into which the piece portion 22a can be inserted. More specifically, the first engagement portion 12 is connected to each of the support wall 11a and the side wall 11b, and has a through hole 12a. The through hole 12a is provided along the extension direction X and has a cross-sectional shape into which the piece portion 22a can be inserted. The first engagement portion 12 has a locking portion 12b that locks the protrusion 22b. The locking portion 12b is formed at a column portion extending in a height direction Z. When the piece portion 22a is inserted into the through hole 12a along the extension direction X, the protrusion 22b is locked by the locking portion 12b, and the first engagement portion 12 and the second engagement portion 22 are engaged with each other. The first engagement portion 12 and the second engagement portion 22 are engaged with each other, whereby the first case 10 and the second case 20 are fixed.

The first coupling portion 13 and the second coupling portion 23 in FIG. 4 constitute a hinge-like rotation structure 40 (see FIG. 1). As illustrated in FIG. 4, the first coupling portion 13 has a pair of tubular portions 14. The tubular portion 14 is disposed at an outer face of the side wall 11b. The two tubular portions 14 are coaxially disposed at intervals in the height direction Z. The height direction Z is a direction orthogonal to both the extension direction X and the width direction Y. The tubular portion 14 has a slit 14s that allows passage of a pin 23b.

The second coupling portion 23 includes a cylindrical main body 23a and a pair of pins 23b. The main body 23a protrudes in the extension direction X from the end face of the side wall 21b. The pin 23b protrudes from the main body 23a in the height direction Z. One pin 23b protrudes toward the support wall 21a, and the other pin 23b protrudes toward a direction opposite to the support wall 21a. The pin 23b has a cylindrical shape and has a smaller diameter than the main body 23a.

The two tubular portions 14 of the first coupling portion 13 rotatably support the pin 23b. That is, the first coupling portion 13 and the second coupling portion 23 are coupled so that the first case 10 and the second case 20 can relatively rotate about the center axis of the pin 23b.

The first case 10 and the second case 20 are connected so as to be either disposed at the first relative position or disposed at the second relative position. The first relative position is a relative position illustrated in FIG. 1. At the first relative position, the first case 10 and the second case 20 are disposed along the width direction Y. In this case, the side wall 11b of the first case 10 and the side wall 21b of the second case 20 face each other in the width direction Y. In the first relative position, the first case 10 and the second case 20 may be disposed in parallel.

The second relative position is a relative position illustrated in FIG. 2. In the second relative position, the first case 10 and the second case 20 are linearly disposed along the extension direction X. In this case, the side wall 21b of the second case 20 is positioned on an extension line of the extension direction X with respect to the side wall 11b of the first case 10. As indicated by an arrow AR1 in FIG. 2, the rotation structure 40 can relatively rotate the second case 20 from the first relative position to the second relative position with respect to the first case 10. The rotation structure 40 guides the second engagement portion 22 to the first engagement portion 12 and engages the second engagement portion 22 with the first engagement portion 12. That is, when the second case 20 is positioned linearly with respect to the first case 10, the first engagement portion 12 and the second engagement portion 22 automatically engage with each other.

The flat wiring material case 1 of the present embodiment is applied to, for example, the flat wiring material 100 illustrated in FIG. 5. The flat wiring material 100 is, for example, a flexible printed circuit (FPC). The flat wiring material 100 of FIG. 5 is disposed in the battery module and detects the voltage and the temperature of the battery cell of the battery module.

When the flat wiring material 100 is an FPC, the flat wiring material 100 includes a base film, a conductive layer, and a coverlay. The conductive layer is sandwiched and protected by the base film and the coverlay. The conductive layer is, for example, a conductive metal foil, and has a circuit pattern including a plurality of detection lines 140. The flat wiring material 100 has flexibility and can be bent and routed.

The flat wiring material 100 of FIG. 5 has a substantially U-shape in plan view. The flat wiring material 100 has a first portion 110, a second portion 120, and an intermediate portion 130. The shapes of the first portion 110 and the second portion 120 in plan view are substantially rectangular. The intermediate portion 130 connects the first portion 110 and the second portion 120. The shape of the intermediate portion 130 in plan view is an arc shape. The flat wiring material 100 has the detection line 140 extending from the first portion 110 to the second portion 120 via the intermediate portion 130.

For example, electronic components such as a fuse and a thermistor, and a metal plate component are mounted on the flat wiring material 100. The flat wiring material 100 having a U shape enables efficiency and cost reduction of a mounting process for mounting various components. A plurality of bus bars 200 is attached to the flat wiring material 100 in FIG. 5. The bus bar 200 is disposed at each of the first portion 110 and the second portion 120. The bus bars 200 are disposed at intervals along the longitudinal direction of the first portion 110 and the second portion 120.

Each bus bar 200 is electrically connected to a detection line 140 for voltage detection. When the thermistor is surface-mounted on the flat wiring material 100, the thermistor is electrically connected to the detection line 140 for temperature detection. Each detection line 140 is connected to, for example, an electronic control unit that monitors the battery module. For example, a chip fuse is mounted on each detection line 140.

As described below, the flat wiring material case 1 of the present embodiment may be used when the flat wiring material 100 having a U-shape is linearly deformed and held. In this case, the flat wiring material case 1 is fitted to the flat wiring material 100 as illustrated in FIG. 6. In the flat wiring material case 1 of FIG. 6, the first case 10 and the second case 20 are positioned at a first relative position. Each component is surface-mounted on the flat wiring material 100 in advance, and the bus bar 200 is attached thereto.

The process of assembling the flat wiring material case 1 with respect to the flat wiring material 100 is executed by, for example, an operator. For example, the operator covers the flat wiring material case 1 with respect to the flat wiring material 100 placed on the jig plate, and fits the flat wiring material case 1 to the flat wiring material 100. The first case 10 of the flat wiring material case 1 is assembled to the first portion 110 of the flat wiring material 100. The second case 20 of the flat wiring material case 1 is assembled to the second portion 120 of the flat wiring material 100.

The flat wiring material case 1 is assembled to the flat wiring material 100 so as to expose the intermediate portion 130 of the flat wiring material 100. As illustrated in FIG. 7, the first portion 110 of the flat wiring material 100 is accommodated in the first case 10. The holding portion 11c of the first case 10 holds the first portion 110 accommodated in the accommodation space 11d. The second portion 120 of the flat wiring material 100 is accommodated in the second case 20. The holding portion 21c of the second case 20 holds the second portion 120 accommodated in the accommodation space 21d.

Next, the first case 10 and the second case 20 are positioned at the second relative position illustrated in FIG. 8. The process of relatively rotating the first case 10 and the second case 20 is executed by, for example, an operator. The operator relatively rotates the second case 20 to the first case 10 to position the first case 10 and the second case 20 at the second relative position. At this time, the intermediate portion 130 of the flat wiring material 100 is flexurally deformed outside the flat wiring material case 1. For example, the intermediate portion 130 is deformed so as to float from the jig plate. When the first case 10 and the second case 20 are positioned at the second relative position, the intermediate portion 130 is accommodated in the flat wiring material case 1. For example, the intermediate portion 130 is folded by mountain folding or valley folding at a line along the radial direction.

FIG. 9 illustrates an example of the intermediate portion 130 accommodated in the flat wiring material case 1. The folded intermediate portion 130 is accommodated in the first case 10, for example. In this case, the intermediate portion 130 may be inserted between the first portion 110 and the main body 11 of the first case 10. The intermediate portion 130 may be accommodated in the second case 20. As illustrated in FIG. 9, the flat wiring material case 1 linearly arranges and holds the first portion 110 and the second portion 120 of the flat wiring material 100 along the extension direction X. The second engagement portion 22 is engaged with the first engagement portion 12 of the flat wiring material case 1, and the first case 10 and the second case 20 are locked.

The flat wiring material case 1 of the present embodiment can linearly deform the flat wiring material 100 having a U-shape. Therefore, the flat wiring material case 1 of the present embodiment can achieve both a reduction in the manufacturing cost and the surface mounting cost of the flat wiring material 100 and an increase in the length of the flat wiring material 100.

In the process of relatively rotating the first case 10 and the second case 20, the flat wiring material 100 is accommodated in the cases 10 and 20 and held by the cases 10 and 20. Therefore, in the relative rotation process, the flat wiring material 100 is prevented from being unexpectedly deformed. In the relative rotation process, the jig plate or the like hardly interferes with the component mounted on the flat wiring material 100, and the mounted component is hardly damaged.

As a comparative example with respect to the flat wiring material case 1 of the present embodiment, a case in which the whole is formed linearly will be described. When the flat wiring material 100 having a U shape is accommodated in the case of the comparative example, a process of deforming the flat wiring material 100 outside the case occurs. The process includes, for example, the work of folding and stretching the flat wiring material 100 to which the bus bar 200 is attached and deforming the flat wiring material into a linear shape. At this time, it is necessary to suppress the movement of the bus bar 200, and for example, a dedicated facility for suppressing the movement of the bus bar 200 is required.

According to the present embodiment, the bus bar 200 and the U-shaped flat wiring material 100 can be placed in the flat wiring material case 1 before the folding and stretching work. Since the bus bar 200 is held by the flat wiring material case 1, the facility for suppressing the movement of the bus bar 200 is unnecessary.

The flat wiring material case 1 holding the flat wiring material 100 may be used as a case of a bus bar module. That is, the flat wiring material case 1 may be attached to the battery module while holding the flat wiring material 100 and the bus bar 200. In this case, a cover that covers the flat wiring material 100 may be attached to the flat wiring material case 1.

FIG. 10 illustrates another example of the flat wiring material case 1 according to the embodiment. The first engagement portion 12 in FIG. 10 is a recess or a through hole formed in the side wall 11b of the first case 10. The second engagement portion 22 includes a piece portion 22c disposed at the side wall 21b of the second case 20 and a protrusion 22d. The piece portion 22c protrudes from the inner face of the side wall 21b and extends toward the first case 10 along the extension direction X. The protrusion 22d protrudes in the width direction Y from the piece portion 22c. When the protrusion 22d is fitted to the first engagement portion 12, the first engagement portion 12 and the second engagement portion 22 are engaged with each other. The first engagement portion 12 and the second engagement portion 22 are engaged with each other, whereby the first case 10 and the second case 20 are fixed.

The first coupling portion 13 and the second coupling portion 23 in FIG. 10 constitute the rotation structure 40 that slidably holds a spherical face. The second coupling portion 23 includes an arm 23c and a ball portion 23d. The arm 23c protrudes in the width direction Y from the outer face of the side wall 21b of the second case 20. The ball portion 23d has a spherical shape and is connected to the distal end of the arm 23c. The second coupling portion 23 has a hollow bearing portion 15 that rotatably holds the ball portion 23d. The shape of the inner face of the bearing portion 15 is a spherical shape. The bearing portion 15 slidably supports the outer peripheral face of the ball portion 23d. The bearing portion 15 has a slit 15s corresponding to the arm 23c. The slit 15s is formed so that the first case 10 and the second case 20 can relatively rotate from the first relative position to the second relative position.

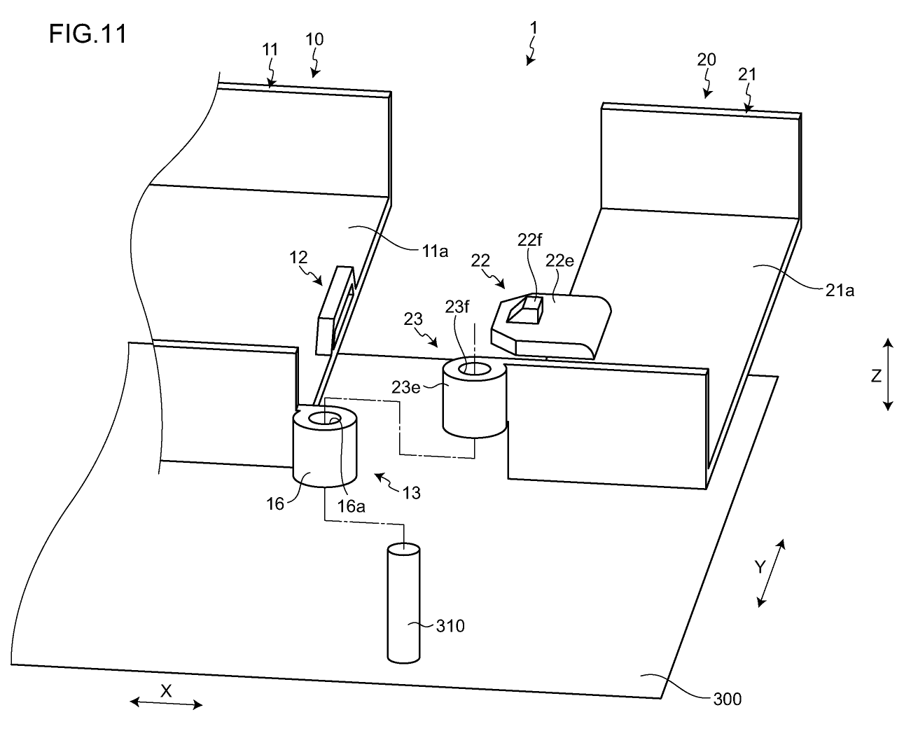

The first coupling portion 13 and the second coupling portion 23 may be coupled by a member such as a pin. The first coupling portion 13 and the second coupling portion 23 in FIG. 11 are connected by a pin 310 of a jig plate 300. The first coupling portion 13 and the second coupling portion 23 have a cylindrical shape. More specifically, the first coupling portion 13 has a tubular portion 16 having a cylindrical shape. The tubular portion 16 is disposed at an end portion of the first case 10, the end portion being coupled to the second case 20. The tubular portion 16 has a through hole 16a penetrating in the height direction Z.

The second coupling portion 23 has a tubular portion 23e having a cylindrical shape. The tubular portion 23e is disposed at an end portion of the second case 20, the end portion being coupled to the first case 10. The tubular portion 23e has a through hole 23f penetrating in the height direction Z. The two tubular portions 16 and 23e are disposed to be shifted in the height direction Z.

The process of relatively rotating the two cases 10 and 20 is executed in the jig plate 300, for example. The jig plate 300 has the pin 310 that can be inserted into the through holes 16a and 23f. By inserting the pin 310 into the two through holes 16a and 23f, the first case 10 and the second case 20 are rotatably coupled.

The second engagement portion 22 in FIG. 11 includes a piece portion 22e and a protrusion 22f. The piece portion 22e protrudes from the end face of the support wall 21a in the extension direction X. The protrusion 22f protrudes from the piece portion 22e in the height direction Z. The first engagement portion 12 has an arch shape into which the piece portion 22e can be inserted. The first engagement portion 12 protrudes from the support wall 11a in the height direction Z. When the second case 20 relatively rotates toward the second relative position with respect to the first case 10, the piece portion 22e is guided and inserted into the first engagement portion 12. When the first engagement portion 12 locks the protrusion 22f, the first engagement portion 12 and the second engagement portion 22 are engaged with each other. The first engagement portion 12 and the second engagement portion 22 are engaged with each other, whereby the first case 10 and the second case 20 are fixed.

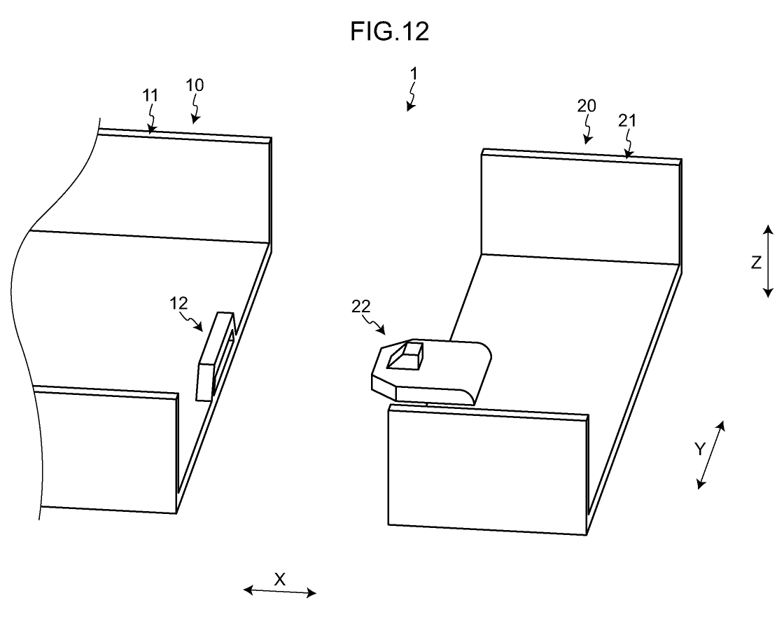

The first case 10 and the second case 20 may not have the rotation structure 40. For example, as illustrated in FIG. 12, the first case 10 may not include the first coupling portion 13. The second case 20 may not include the second coupling portion 23. The first case 10 and the second case 20 in FIG. 12 can be either disposed at the first relative position or disposed at the second relative position. The process of engaging the first case 10 with the second case 20 is performed by, for example, an operator. The flat wiring material case 1 may have a guide structure that guides the second engagement portion 22 to the first engagement portion 12.

The application target of the flat wiring material case 1 is not limited to the flat wiring material 100 having a U-shape. For example, the flat wiring material case 1 may be applied to a linear flat wiring material 100 illustrated in FIG. 13. In the flat wiring material case 1 of FIG. 13, the first case 10 and the second case 20 are linearly engaged. The flat wiring material 100 is accommodated in the first case 10 and the second case 20 that are linearly engaged. In the flat wiring material case 1 of the present embodiment, the cases 10 and 20 can be downsized for the long flat wiring material 100.

The flat wiring material 100 accommodated in the flat wiring material case 1 may be configured by connecting a plurality of portions. For example, as illustrated in FIG. 14, the flat wiring material 100 may include a first wiring material 100A and a second wiring material 100B that can be connected. The first wiring material 100A and the second wiring material 100B are each formed linearly.

A connector 150 is disposed at the first wiring material 100A. The detection line 140 of the first wiring material 100A is connected to the terminal of the connector 150. A connector 160 is disposed at the second wiring material 100B. The detection line 140 of the second wiring material 100B is connected to the terminal of the connector 160.

The first wiring material 100A is accommodated in the first case 10 as a first portion of the flat wiring material 100. The second wiring material 100B is accommodated in the second case 20 as a second portion of the flat wiring material 100. The flat wiring material case 1 accommodating the two wiring materials 100A and 100B can be conveyed, for example, in a state where the first case 10 and the second case 20 are positioned at a first relative position as illustrated in FIG. 1.

When the flat wiring material 100 is assembled to the battery module, the flat wiring material case 1 is deformed into the state illustrated in FIG. 14. At this time, the two wiring materials 100A and 100B are configured as one flat wiring material 100 by connecting the two connectors 150, 160.

As described above, the flat wiring material case 1 of the present embodiment includes the first case 10 and the second case 20. The first case 10 includes the accommodation space 11d in which the first portion 110 of the flat wiring material 100 is accommodated, the holding portion 11c that holds the first portion 110, and the first engagement portion 12. The second case 20 includes the accommodation space 21d in which the second portion 120 of the flat wiring material 100 is accommodated, the holding portion 21c that holds the second portion 120, and the second engagement portion 22. The first case 10 and the second case 20 have an extension direction X in which the flat wiring material 100 extends.

The first case 10 and the second case 20 are configured to be either disposed at the first relative position or disposed at the second relative position. In the first relative position, the first case 10 and the second case 20 are disposed in a direction orthogonal to the extension direction X. In the second relative position, the first case 10 and the second case 20 are linearly disposed along the extension direction X. In the second relative position, the first engagement portion 12 and the second engagement portion 22 are engaged with each other to fix the first case 10 and the second case 20. Since the flat wiring material case 1 of the present embodiment includes the two engageable cases 10 and 20, the cost can be reduced. For example, the manufacturing cost is reduced by downsizing of the cases 10 and 20. For example, since the cases 10 and 20 can be positioned at the first relative position, the conveyance cost is reduced.

The flat wiring material case 1 may have a rotation structure 40. The rotation structure 40 relatively rotates the first case 10 and the second case 20 between the first relative position and the second relative position. The rotation structure 40 can improve work efficiency when the two cases 10 and 20 are relatively rotated.

The flat wiring material case 1 may have three or more sub cases. The flat wiring material case 1 illustrated in FIG. 15 includes a third case 30 in addition to the first case 10 and the second case 20. The third case 30 includes a main body 31 and a third engagement portion 32. The first case 10 has an engagement portion 17 corresponding to the third engagement portion 32. The flat wiring material case 1 has a rotation structure 50 that rotatably connects the first case 10 and the third case 30.

As illustrated in FIG. 15, the third case 30 can be positioned at a first relative position with respect to the first case 10. The third case 30 relatively rotates with respect to the first case 10, and can be positioned at the second relative position with respect to the first case 10. According to the flat wiring material case 1 illustrated in FIG. 15, downsizing of the cases 10, 20, and 30 is realized.

Note that the flat wiring material 100 is not limited to being made of the FPC. The flat wiring material 100 may be made of, for example, another flat wiring material such as a flexible flat cable (FFC).

The bus bar 200 may be attached to the flat wiring material 100 after the flat wiring material 100 is accommodated in the flat wiring material case 1. Components such as electronic components may be surface-mounted on the flat wiring material 100 accommodated in the flat wiring material case 1.

The shape of the intermediate portion 130 is not limited to the illustrated arc shape. The intermediate portion 130 may have, for example, a substantially V-shape as illustrated in FIG. 16. The intermediate portion 130 in FIG. 16 has a first inclined portion 131 connected to the first portion 110 and a second inclined portion 132 connected to the second portion 120. The first inclined portion 131 is inclined toward the second portion 120 with increasing distance from the first portion 110 along the longitudinal direction Ex of the first portion 110. The second inclined portion 132 is inclined toward the first portion 110 with increasing distance from the second portion 120 along the longitudinal direction Ex of the second portion 120. The first inclined portion 131 and the second inclined portion 132 intersect so as to form a V shape in plan view.

For example, the intermediate portion 130 may be bent at a right angle as illustrated in FIG. 17. The intermediate portion 130 in FIG. 17 has a first extension portion 133 connected to the first portion 110, a second extension portion 134 connected to the second portion 120, and a connection portion 135. The first extension portion 133 extends from the first portion 110 along the longitudinal direction Ex and protrudes from the first case 10. The second extension portion 134 extends from the second portion 120 along the longitudinal direction Ex and protrudes from the second case 20. The connection portion 135 connects the distal end of the first extension portion 133 and the distal end of the second extension portion 134. The connection portion 135 extends along the direction Ot orthogonal to the longitudinal direction Ex.

### Modification of embodiment

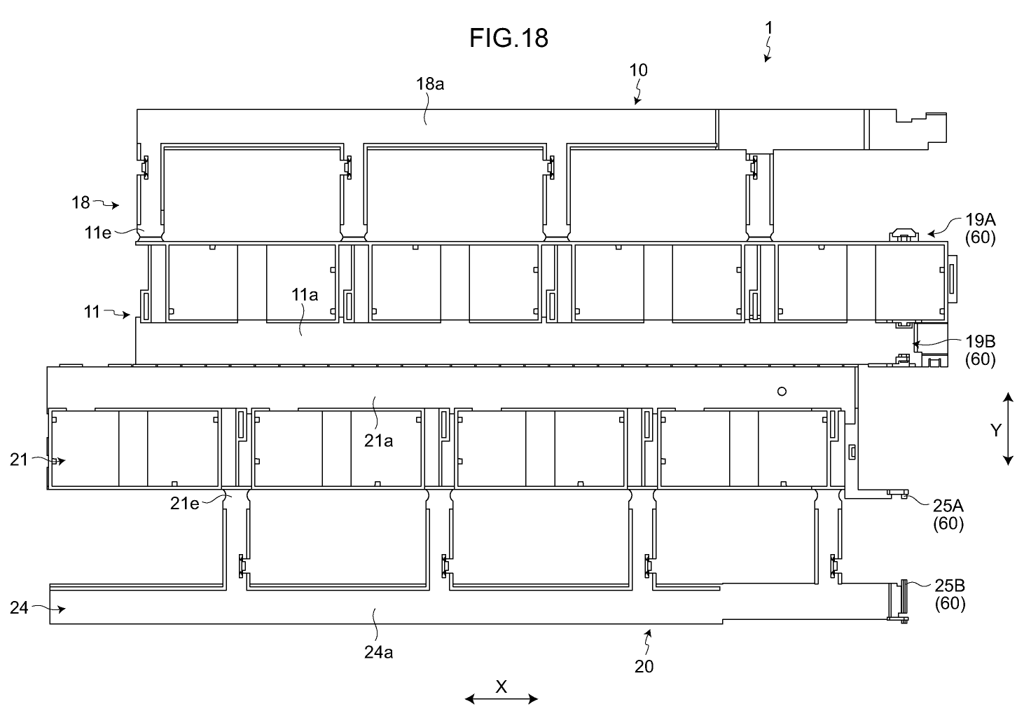

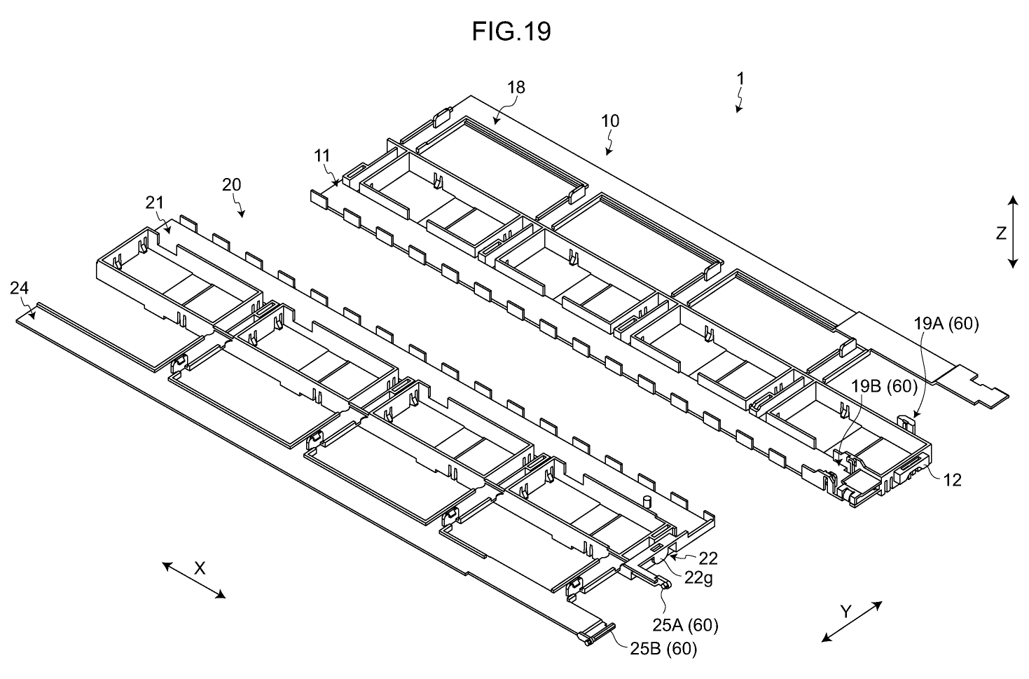

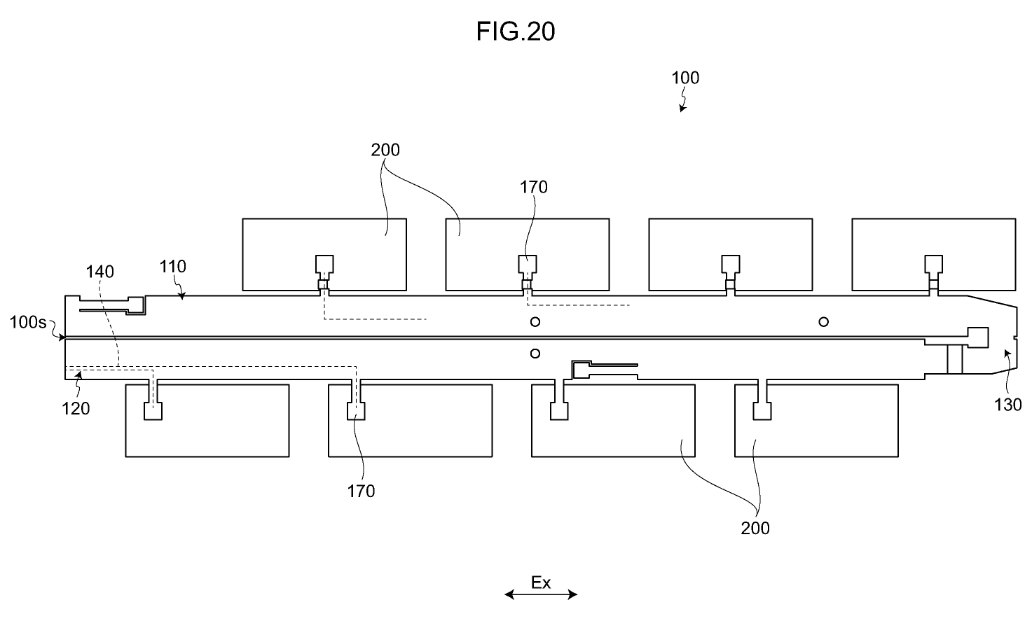

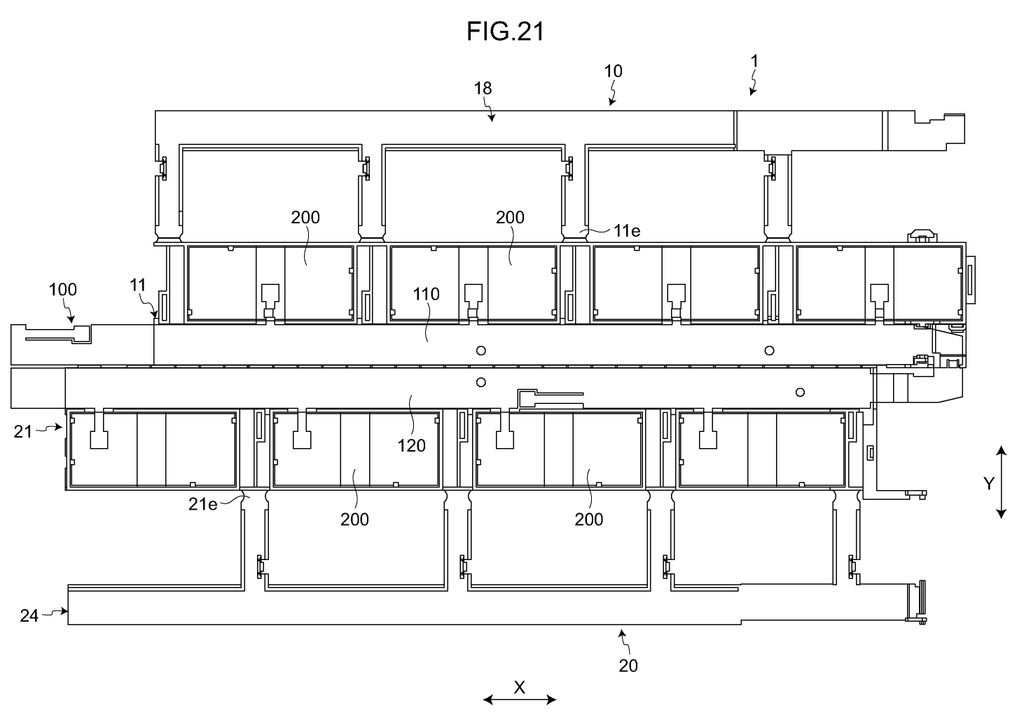

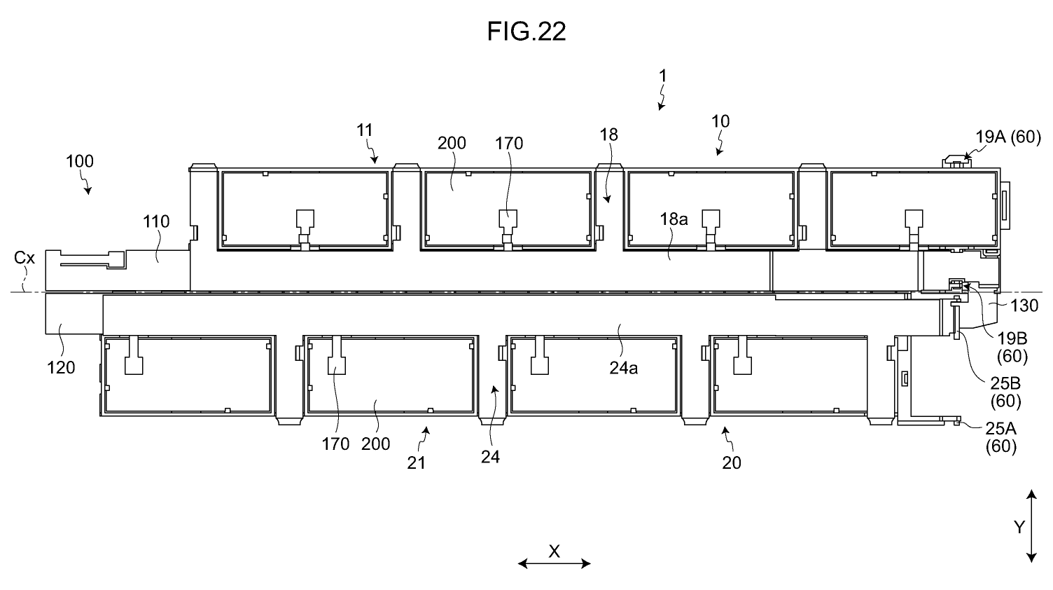

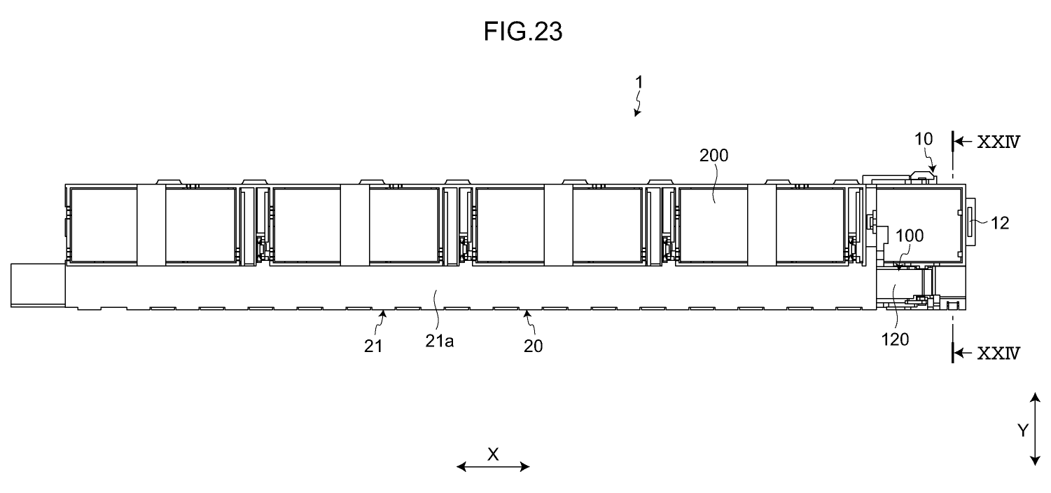

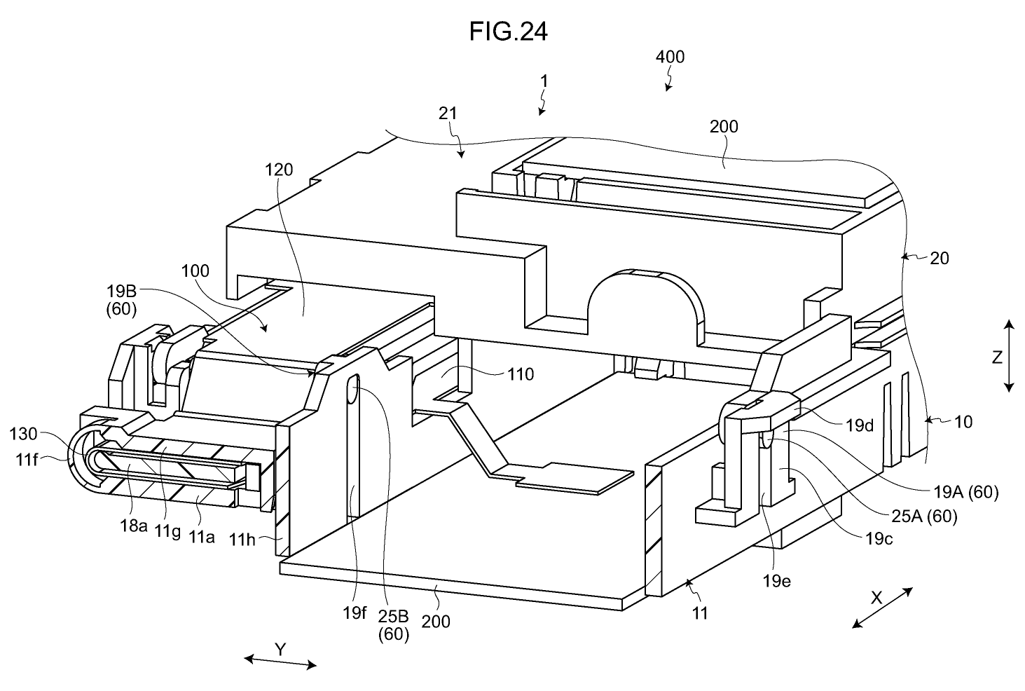

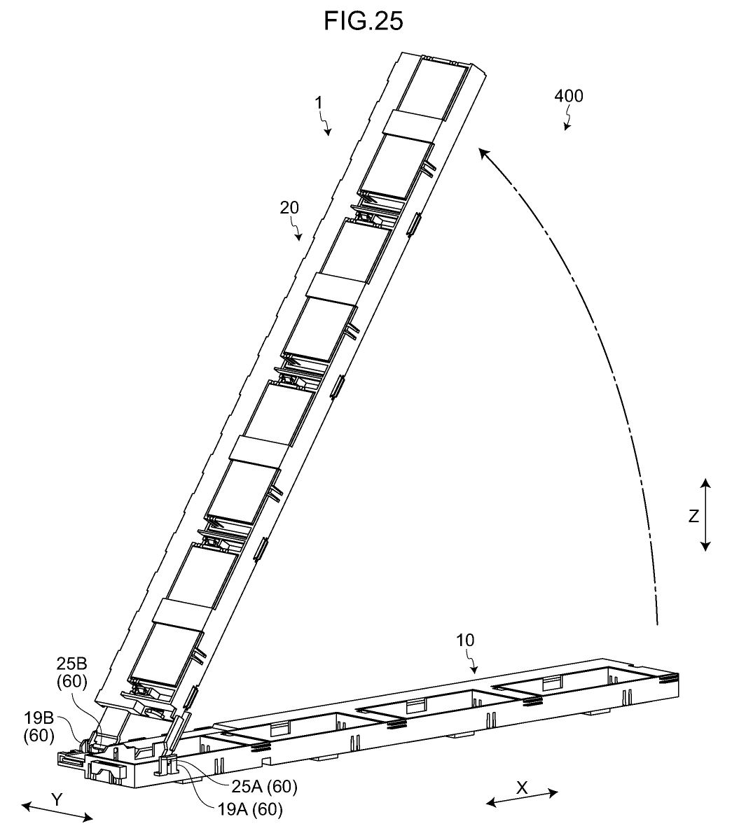

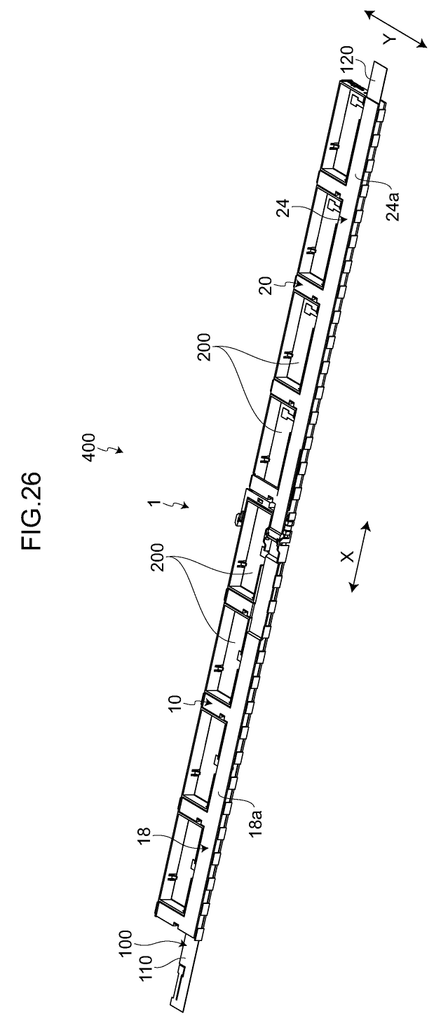

The flat wiring material case 1 according to a modification of the embodiment will be described. FIG. 18 is a developed view of a flat wiring material case according to a modification of the embodiment, FIG. 19 is a perspective view of the flat wiring material case according to the modification of the embodiment, FIG. 20 is a plan view of the flat wiring material according to the modification of the embodiment, FIG. 21 is a plan view illustrating the flat wiring material accommodated in a case according to the modification of the embodiment, FIG. 22 is a plan view of the flat wiring material case in a state where a cover is closed, FIG. 23 is a plan view illustrating the first case and a second case positioned at an intermediate relative position, FIG. 24 is a cross-sectional perspective view illustrating the bent flat wiring material, FIG. 25 is a perspective view for describing relative rotation of the second case with respect to the first case, and FIG. 26 is a perspective view of the first case and the second case positioned at a second relative position.

The flat wiring material case 1 according to the modification of the embodiment is different from the flat wiring material case 1 of the above embodiment in that, for example, the first case 10 and the second case 20 are configured to be positioned at an intermediate relative position. In the intermediate relative position, as illustrated in FIG. 24, the first case 10 and the second case 20 overlap each other so that the first portion 110 and the second portion 120 of the flat wiring material 100 face each other.

In the flat wiring material case 1 according to the modification of the embodiment, the first case 10 and the second case 20 are positioned at an intermediate relative position between the first relative position and the second relative position. As illustrated in FIG. 25, the first case 10 and the second case 20 are coupled so as to be relatively rotatable. The second case 20 relatively rotates with respect to the first case 10 from the intermediate relative position toward the second relative position. The flat wiring material case 1 according to the modification of the embodiment is conveyed, for example, in a state where the first case 10 and the second case 20 are positioned at an intermediate relative position. Since the first case 10 and the second case 20 overlap with each other, it is possible to improve the conveyability.

As illustrated in FIG. 18, the first case 10 according to a modification of the embodiment includes the main body 11 and a cover 18. The main body 11 and the cover 18 are integrally molded, for example. In the first case 10 of FIG. 18, the main body 11 and the cover 18 are connected via a hinge portion 11e. The main body 11 has the support wall 11a that supports the first portion 110 of the flat wiring material 100. The support wall 11a is formed linearly along the extension direction X. The cover 18 has a facing wall 18a that covers the support wall 11a. The first portion 110 of the flat wiring material 100 is accommodated and held between the support wall 11a and the facing wall 18a.

A first shaft support portion 19A and a second shaft support portion 19B are provided at an end portion of the main body 11 in the extension direction X. The first shaft support portion 19A rotatably supports a first rotation shaft 25A of the second case 20. The second shaft support portion 19B rotatably supports a second rotation shaft 25B of the second case 20.

The second case 20 according to the modification of the embodiment includes the main body 21 and a cover 24. The main body 21 and the cover 24 are integrally molded, for example. In the second case 20 of FIG. 18, the main body 21 and the cover 24 are connected via a hinge portion 21e. The main body 21 has the support wall 21a that supports the second portion 120 of the flat wiring material 100. The support wall 21a is formed linearly along the extension direction X. The cover 24 has a facing wall 24a that covers the support wall 21a. The second portion 120 of the flat wiring material 100 is accommodated and held between the support wall 21a and the facing wall 24a.

The first rotation shaft 25A is provided at an end portion of the main body 21 in the extension direction X. The second rotation shaft 25B is provided at an end portion of the cover 24 in the extension direction X. The first rotation shaft 25A protrudes in the width direction Y from the face of the main body 21. The second rotation shaft 25B extends in the width direction Y so as to cross the end portion of the cover 24. Both end portions of the second rotation shaft 25B are supported by the second shaft support portion 19B.

In the flat wiring material case 1 according to the modification of the embodiment, a rotation structure 60 is configured by the two shaft support portions 19A and 19B of the first case 10 and the two rotation shafts 25A and 25B of the second case 20. The rotation structure 60 enables relative rotation of the two cases 10 and 20 as illustrated in FIG. 25.

As illustrated in FIG. 19, the first case 10 includes the first engagement portion 12, and the second case 20 includes the second engagement portion 22. The first engagement portion 12 is disposed at an end portion of the main body 11 in the extension direction X. The second engagement portion 22 is disposed at an end portion of the main body 21 in the extension direction X. The two engagement portions 12 and 22 engage with each other at the second relative position illustrated in FIG. 26.

The second engagement portion 22 in FIG. 19 has a piece portion 22g erected in the height direction Z so as to face the end face of the main body 21. The second engagement portion 22 has a protrusion protruding in the extension direction X from the piece portion 22g. The first engagement portion 12 in FIG. 19 has a frame shape into which the piece portion 22g can be inserted. The first engagement portion 12 protrudes from the end face of the main body 11 in the extension direction X, and has a through hole penetrating in the height direction Z. The first engagement portion 12 and the second engagement portion 22 are engaged with each other, whereby the first case 10 and the second case 20 are fixed.

The flat wiring material case 1 of the modification of the embodiment is applied to, for example, the flat wiring material 100 illustrated in FIG. 20. The flat wiring material 100 is, for example, a flexible printed circuit (FPC). The flat wiring material 100 of FIG. 20 is disposed, for example, in a battery module.

The flat wiring material 100 of FIG. 20 has a substantially U shape in plan view. The flat wiring material 100 has a first portion 110, a second portion 120, and an intermediate portion 130. The shapes of the first portion 110 and the second portion 120 in plan view are substantially rectangular. The flat wiring material 100 has a slit 100s formed between the first portion 110 and the second portion 120.

The intermediate portion 130 connects the first portion 110 and the second portion 120. The shape of the intermediate portion 130 in plan view is substantially trapezoidal. The intermediate portion 130 has a tapered shape whose width decreases with increasing distance from the first portion 110 and the second portion 120 along the longitudinal direction Ex.

The flat wiring material 100 according to the modification of the embodiment has a branch portion 170 connected to the bus bar 200. The branch portion 170 extends in the width direction from the first portion 110 and the second portion 120. The distal end portion of the branch portion 170 is connected to a bus bar 200 by solder or the like.

FIG. 21 illustrates the flat wiring material 100 accommodated in the flat wiring material case 1. The first portion 110 is accommodated in the main body 11 of the first case 10. The bus bar 200 connected to the first portion 110 is accommodated in the main body 11 and held by the main body 11. The second portion 120 is accommodated in the main body 21 of the second case 20. The bus bar 200 connected to the second portion 120 is accommodated in the main body 21 and held by the main body 21.

The process of accommodating the flat wiring material 100 in the flat wiring material case 1 is executed using, for example, a jig plate. As an example, the flat wiring material 100 may be assembled to the first case 10 and the second case 20 placed on the jig plate. At this time, the first case 10 and the second case 20 are placed on the jig plate at the first relative position. The operator places the first portion 110 of the flat wiring material 100 on the main body 11 of the first case 10, and places the second portion 120 of the flat wiring material 100 on the main body 21 of the second case 20. When the bus bar 200 is attached to the flat wiring material 100 in advance, the bus bar 200 together with the flat wiring material 100 is assembled to the main bodies 11 and 21.

When the flat wiring material 100 is accommodated in the two cases 10 and 20, a closing process of closing the covers 18 and 24 is executed. In the closing process, the cover 18 of the first case 10 is assembled to the main body 11 while bending the hinge portion 11e. In the closing process, the cover 24 of the second case 20 is assembled to the main body 21 while bending the hinge portion 21e. FIG. 22 illustrates a state in which the covers 18 and 24 are closed. The facing wall 18a of the cover 18 covers the first portion 110 of the flat wiring material 100. The facing wall 24a of the cover 24 covers the second portion 120 of the flat wiring material 100.

When the cover 24 is closed, the second rotation shaft 25B of the second case 20 is positioned at a position adjacent to the second shaft support portion 19B of the first case 10. The first rotation shaft 25A of the second case 20 is located at an end portion far from the first case 10 in the width direction Y. The first shaft support portion 19A of the first case 10 is located at an end portion far from the second case 20 in the width direction Y.

From the state illustrated in FIG. 22, a first rotating process of relatively rotating the second case 20 with respect to the first case 10 is executed. In the first rotating process, the second case 20 is rotated with respect to the first case 10 about a rotation axis Cx illustrated in FIG. 22 as a rotation center. The rotation axis Cx is, for example, a straight line extending in the extension direction X between the two covers 18 and 24. The rotation at this time may be executed using, for example, a jig plate. In this case, the jig plate may include a main body that supports the first case 10 and a support member that supports the second case 20. The support member is supported by the main body so as to be rotatable about the rotation axis Cx.

The second case 20 relatively rotates with respect to the first case 10 about the rotation axis Cx, and the second case 20 is overlapped with the first case 10. As a result, the second portion 120 of the flat wiring material 100 overlaps the first portion 110 and faces the first portion 110. At this time, the intermediate portion 130 of the flat wiring material 100 is bent along the rotation axis Cx.

FIG. 23 illustrates a state in which the first rotating process is completed and the second case 20 is overlapped with the first case 10. FIG. 24 illustrates a cross section taken along XXIV-XXIV in FIG. 23. As illustrated in FIGS. 23 and 24, the first case 10 includes a protective cover 11g that protects the intermediate portion 130 of the flat wiring material 100. The protective cover 11g is connected to a support wall 11a via a hinge portion 11f. The first case 10 accommodates the intermediate portion 130 folded back in a U shape between the support wall 11a and the protective cover 11g. The facing wall 18a of the cover 18 is sandwiched inside the folded intermediate portion 130.

The first rotation shaft 25A of the second case 20 is rotatably supported by the first shaft support portion 19A of the first case 10. The first shaft support portion 19A includes a piece portion 19c erected in the height direction Z and a locking portion 19d. The piece portion 19c has a slit 19e extending in the height direction Z. The end portion of the first rotation shaft 25A is inserted into a slit 19e and locked by the locking portion 19d.

The second rotation shaft 25B of the second case 20 is rotatably supported by the second shaft support portion 19B of the first case 10. The second shaft support portion 19B has a slit 19f provided in a side wall 11h. The side walls 11h are disposed at both sides of the support wall 11a in the width direction Y. The end portion of the second rotation shaft 25B is inserted into a slit 19f and rotatably supported by the side wall 11h. By inserting the two rotation shafts 25A and 25B into the two shaft support portions 19A and 19B, the first case 10 and the second case 20 are rotatably coupled. Thus, the bus bar module 400 is configured. The bus bar module 400 includes the flat wiring material case 1 of the embodiment, the flat wiring material 100, and the bus bar 200.

FIG. 25 is a diagram for describing the second rotating process. The second rotating process is executed, for example, in a factory in which the bus bar module 400 is assembled to a vehicle or the like. As illustrated in FIG. 25, in the second rotating process, the second case 20 is relatively rotated with respect to the first case 10 from the intermediate relative position toward the second relative position. In the second rotating process, the second case 20 relatively rotates with respect to the first case 10 about the center axis of the two rotation shafts 25A as the rotation center.

FIG. 26 illustrates a state in which the second rotating process is completed and the two cases 10 and 20 are positioned at the second relative position. The first portion 110 and the second portion 120 of the flat wiring material 100 are disposed in a straight line. In other words, the second portion 120 is positioned on the extension line of the first portion 110 in plan view. Further, the plurality of bus bars 200 is linearly disposed along the extension direction X. The cover 18 of the first case 10 covers the first portion 110 by the facing wall 18a to protect the first portion 110. The cover 24 of the second case 20 covers the second portion 120 by the facing wall 24a to protect the second portion 120.

When the two cases 10 and 20 are positioned at the second relative position, the bus bar module 400 is assembled to the battery pack. Each bus bar 200 is connected to an electrode of a battery cell included in the battery pack. The detection line 140 of the flat wiring material 100 is connected to, for example, a monitoring unit that monitors the state of the battery cell. In the flat wiring material case 1 of the present embodiment, the flat wiring material 100 and the flat wiring material case 1 can be conveyed in a state where the two cases 10 and 20 overlap. Therefore, according to the flat wiring material case 1 of the present embodiment, it is possible to improve the conveyability.

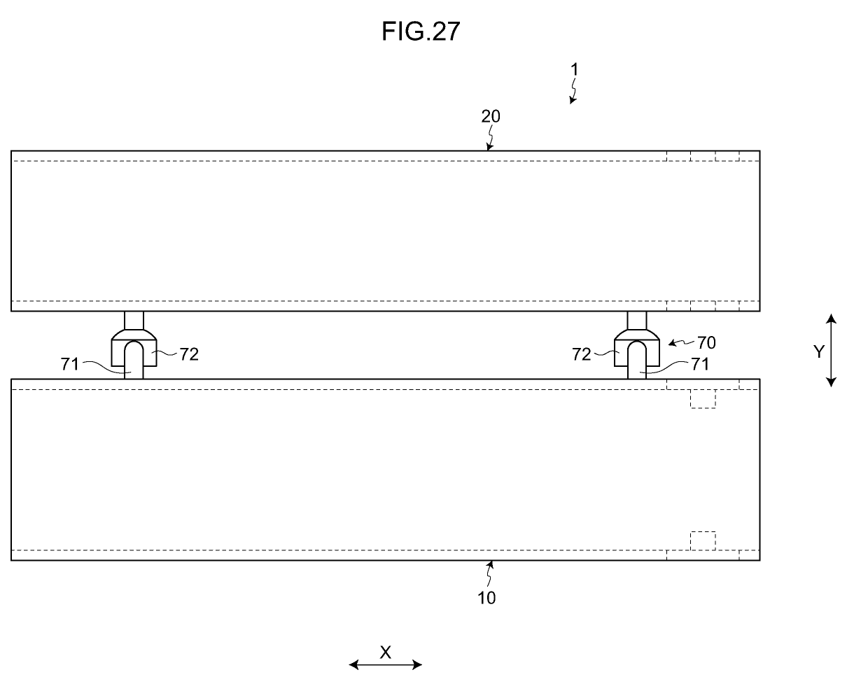

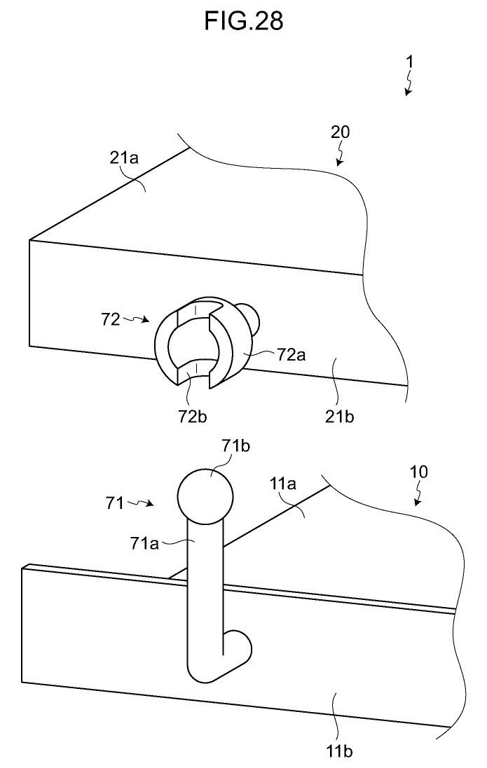

Note that the flat wiring material case 1 may have a coupling structure 70 described below. FIG. 27 illustrates the flat wiring material case 1 having the coupling structure 70. The coupling structure 70 includes a first coupling portion 71 and a second coupling portion 72.

The first coupling portion 71 includes an arm 71a and a ball portion 71b. The proximal end portion of the arm 71a protrudes in the width direction Y from the outer face of the side wall 11b of the first case 10. The arm 71a is bent at a substantially right angle at the intermediate portion. The distal end portion of the arm 71a extends in the height direction Z. The ball portion 71b is disposed at the distal end of the arm 71a. The ball portion 71b has a spherical shape.

The second coupling portion 72 is disposed at the outer face of the side wall 21b of the second case 20. The second coupling portion 72 has a hollow bearing portion 72a that rotatably holds the ball portion 71b. The shape of the inner face of the bearing portion 72a is a spherical shape. The bearing portion 72a slidably supports the outer peripheral face of the ball portion 71b. The bearing portion 72a has a slit 72b corresponding to the arm 71a. The slit 72b is formed so that the first case 10 and the second case 20 can relatively rotate from the first relative position to the intermediate relative position.

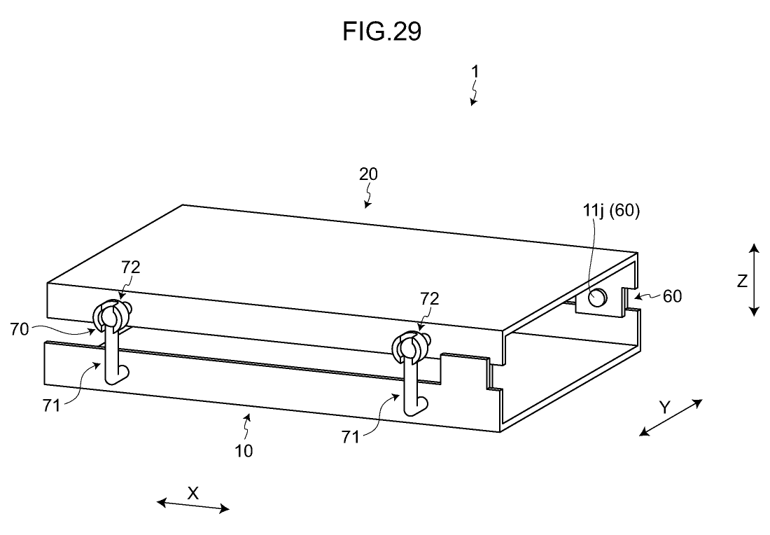

As illustrated in FIG. 27, the coupling structure 70 is configured to be able to position the first case 10 and the second case 20 at a first relative position. In addition, the coupling structure 70 is configured to be able to position the first case 10 and the second case 20 at an intermediate relative position as illustrated in FIG. 29.

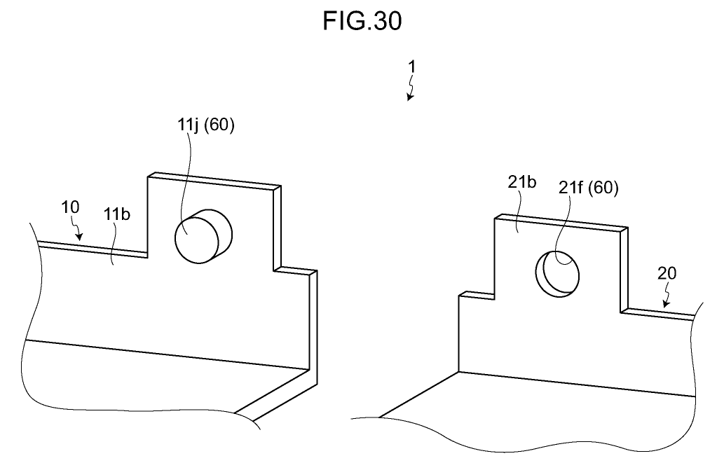

As illustrated in FIG. 29, the flat wiring material case 1 has the rotation structure 60. As illustrated in FIG. 30, the rotation structure 60 includes a protrusion 11j of the first case 10 and a recess 21f of the second case 20. The protrusion 11j protrudes from the inner face of the side wall 11b. The shape of the protrusion 11j is, for example, a cylindrical shape. The first case 10 has two protrusions 11j facing each other in the width direction Y.

The recess 21f is provided in the side wall 21b, and the protrusion 11j can be inserted into the recess 21f. The recess 21f may be a through hole penetrating the side wall 21b. The second case 20 has two recesses 21f corresponding to the two protrusions 11j. When the first case 10 and the second case 20 are positioned at the intermediate relative position, the two protrusions 11j are inserted into the corresponding recesses 21f. The rotation structure 60 can relatively rotate the two cases 10 and 20 from the intermediate relative position to the second relative position.

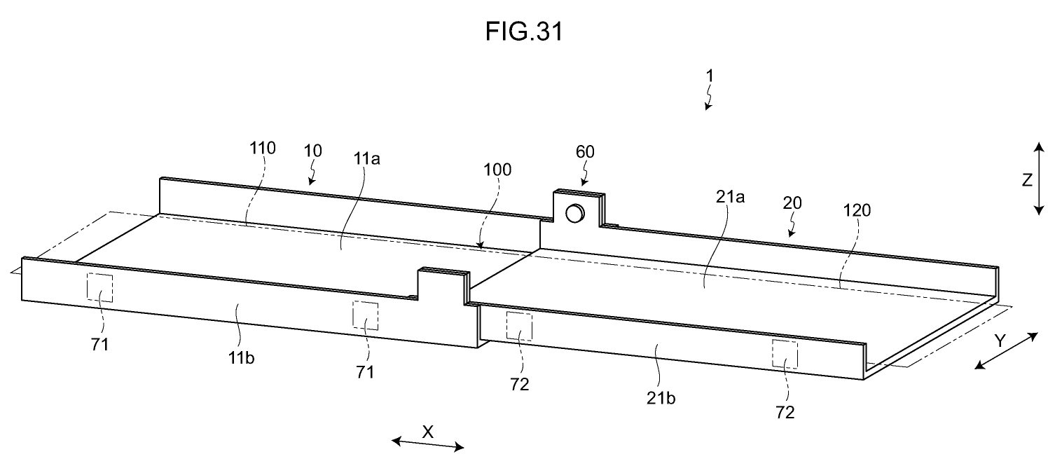

FIG. 31 illustrates the first case 10 and the second case 20 positioned at the second relative position. When the second rotating process is performed, the second coupling portion 72 is separated from the first coupling portion 71. The work of releasing the coupling state of the two coupling portions 71 and 72 may be performed by an operator. When the two cases 10 and 20 are positioned at the second relative position, the first portion 110 and the second portion 120 of the flat wiring material 100 are linearly disposed.

As described above, the flat wiring material case 1 according to the modification of the embodiment has the rotation structure 60. The first case 10 and the second case 20 are configured to be disposed at an intermediate relative position. In the intermediate relative position, the first case 10 and the second case 20 overlap each other so that the first portion 110 and the second portion 120 of the flat wiring material 100 face each other. The rotation structure 60 is configured to allow the first case 10 and the second case 20 to relatively rotate between the intermediate relative position and the second relative position. According to the flat wiring material case 1 according to the modification of the embodiment, it is possible to improve the conveyability.

The flat wiring material case 1 according to the modification of the embodiment may have the coupling structure 70. The coupling structure 70 couples the first case 10 and the second case 20 so that the first case 10 and the second case 20 are relatively rotatable between the first relative position and the intermediate relative position. Such a coupling structure 70 can improve work efficiency in the first rotating process. For example, the first rotating process can be performed without using a dedicated jig plate.

The content disclosed in the above embodiments and modifications can be appropriately combined and executed.

In the flat wiring material case according to the present embodiment, the first case and the second case are configured to be either disposed at the first relative position or disposed at the second relative position. In the first relative position, the first case and the second case are disposed in a direction orthogonal to the extension direction, and in the second relative position, the first case and the second case are linearly disposed along the extension direction. In the second relative position, the first engagement portion and the second engagement portion are engaged with each other to fix the first case and the second case. According to the flat wiring material case of the present embodiment, there is an effect that the conveyability can be improved.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A flat wiring material case comprising:
a first case including an accommodation space in which a first portion of a flat wiring material is accommodated, a holding portion that holds the first portion, and a first engagement portion; and
a second case including an accommodation space in which a second portion of the flat wiring material is accommodated, a holding portion that holds the second portion, and a second engagement portion,
wherein the first case and the second case have an extension direction in which the flat wiring material extends,
wherein the first case and the second case are configured to be either disposed at a first relative position or disposed at a second relative position,
wherein the first case and the second case are disposed side by side in a direction orthogonal to the extension direction and in a width direction of the flat wiring material accommodated in the first case and the second case at the first relative position,
wherein the first case and the second case are linearly disposed along the extension direction at the second relative position, and
wherein the first engagement portion and the second engagement portion are engaged with each other at the second relative position to fix the first case and the second case.

2. The flat wiring material case according to claim 1, further comprising:
a rotation structure that relatively rotates the first case and the second case between the first relative position and the second relative position.

3. The flat wiring material case according to claim 1, further comprising:
a rotation structure,
wherein the first case and the second case are configured to be disposed at an intermediate relative position,
wherein the first case and the second case overlap each other at the intermediate relative position so that the first portion and the second portion of the flat wiring material face each other, and
wherein the rotation structure is configured to relatively rotate the first case and the second case between the intermediate relative position and the second relative position.

4. The flat wiring material case according to claim 3, further comprising:
a coupling structure that couples the first case and the second case so that the first case and the second case are relatively rotatable between the first relative position and the intermediate relative position.
